(19) United States
(12) Patent Application Publication
(10) Pub. No.: US 2006/0085704 A1
(43) Pub. Date: Apr. 20, 2006

(54) Semi-conductor component, as well as a process for the reading of test data

(75) Inventor: Robert Kaiser, Kaufering (DE)

Correspondence Address: MORRISON & FOERSTER LLP, 1650 TYSONS BOULEVARD, SUITE 300, MCLEAN, VA, 22102, US

(73) Assignee: INFINEON TECHNOLOGIES AG, Munchen (DE)

(21) Appl. No.: 11/227,452

(22) Filed: Sep. 16, 2005

(30) Foreign Application Priority Data
Oct. 14, 2004 (DE) 10 2004 050 104.1

(51) Int. Cl. G11C 29/00

(52) U.S. Cl. 714/718

(57) ABSTRACT

The invention relates to a semi-conductor component (2a, 2b), and a process for reading test data, whereby the process comprises the steps:
(a) Reading test data generated during a semi-conductor component test procedure from at least one test data register (102a) of a semi-conductor component (2a),
(b) Storing the test data in at least one useful data memory cell on the semi-conductor component (2a), and (c) Reading the test data from the at least one useful data memory cell.

### CLAIM FOR PRIORITY

This application claims the benefit of priority to German Application No. 10 2004 003 050 104.1 which was filed in the German language on Oct. 14, 2004, the contents of which are hereby incorporated by reference.

### TECHNICAL FIELD OF THE INVENTION

The invention relates to a semi-conductor component, as well as to a process for reading test data.

### BACKGROUND OF THE INVENTION

Semi-conductor components, e.g. corresponding integrated (analog and/or digital) computing circuits, semi-conductor memory components such as for instance function memory components (PLAs, PALs, etc.) and table memory components (e.g. ROMs or RAMs, particularly SRAMs and DRAMs), etc. are subjected to numerous tests in the course of the manufacturing process.

For the simultaneous manufacture of numerous (generally identical) semi-conductor components, a so-called wafer (i.e. a thin disk consisting of monocrystalline silicon) is used. The wafer is appropriately processed (e.g. subjected to numerous coating, lighting, etching, diffusion and implantation process steps, etc.), and subsequently sawn up (or e.g. scored and snapped off), so that the individual components are made available.

During the manufacture of semi-conductor components (e.g. DRAMs (Dynamic Random Access Memories and/or dynamic Read/Write memories), particularly of DDR-DRAMs (Double data Rate - DRAMs and/or DRAMs with double data rate)) the components (still on the wafer and incomplete) may be subjected to corresponding test procedures (e.g. so-called kerf measurements at the scoring grid) even before all the required above processing steps have been performed on the wafer (i.e. even while the semi-conductor components are still semi-complete) at one or several test stations by means of one or several test apparatuses.

After the semi-conductor components have been completed (i.e. after all the above wafer processing steps have been executed) the semi-conductor components are subjected to further test procedures at one or several (further) test stations—for instance the components—still present on the wafer and completed—may be tested with the help of corresponding (further) test apparatuses (“disk tests”).

In similar fashion several further tests may be performed (at corresponding further test stations and by using corresponding additional test equipment) e.g. after the semi-conductor components have been installed in corresponding semi-conductor-component housings, and/or e.g. after the semi-conductor component housings (together with the semi-conductor components installed in them) have been installed in corresponding electronic modules (so-called “module tests”).

During the testing of the semi-conductor components (e.g. during the above disk tests, module tests, etc.), so-called DC tests and/or e.g. so-called AC tests may be applied as test procedures.

During a DC test for instance a voltage (or current) at a specific—in particular a constant—level may be applied to a corresponding connection of a semi-conductor component to be tested, whereafter the level of the—resulting—currents (and/or voltages) is measured—in particular tested to see whether these currents (and/or voltages) fall within predetermined required critical values.

During an AC test in contrast, voltages (or currents) at varying levels, particularly corresponding test pattern signals, can for instance be applied to the corresponding connections of a semi-conductor component, with the help of which appropriate function tests may be performed on the semi-conductor component in question.

With the aid of above test procedures, defective semi-conductor components and/or modules can be identified and then eliminated out (or else partially repaired), and/or the process parameters—used during the manufacture of the components in each case—can be appropriately modified and/or optimized in accordance with the test results achieved, etc., etc.

In case of numerous applications—e.g. at server or work station computers, etc., etc.—memory modules with data buffer components (so-called buffers) connected in series, e.g. so-called “buffered DIMMs”, may be installed.

Memory modules of this nature generally contain one or several semi-conductor memory components, particularly DRAMs, (e.g. DDR-DRAMs) as well as one or several data buffer components such as DRAMs (e.g. corresponding DDR-DRAM data buffer components as standardized by Jedec)—connected in series before the semi-conductor memory components.

These data buffer components may for instance be installed on the same printed circuit board (card) as the DRAMs.

The memory modules are connected—particularly by interconnecting a corresponding memory controller (e.g. arranged externally to the memory module in question)—with one or several micro-processors of that particular server or work station computer, etc.

In “partially” buffered memory modules the address and control signals—e.g. those emitted by the memory controller, or by the processor in question—may be (briefly) retained by corresponding data buffer components, and correspondingly similar address and control signals may be relayed—in chronologically co-ordinated, or where appropriate, in de-multiplexed fashion—to the memory components, e.g. DRAMs.

In contrast, the (useful) data signals—emitted by the memory controller and/or by the respective processor—may be directly—i.e. without being buffered by a corresponding data buffer component (buffer)—relayed to the memory components (and—conversely—the (useful)data signals emitted by the memory components may be directly—without a corresponding data buffer component (buffer) being connected in series—relayed to the memory controller and/or the respective processor).

In “fully buffered” memory modules in contrast, the address and control signals exchanged between the memory controller (and/or the respective processor), and the memory components, and also the corresponding (useful) data signals can first be retained by corresponding data buffer components, and only then relayed to the memory components and/or the memory controller (or the respective processor).

For storing the data, especially corresponding test (result) data, generated during the above test procedures (or any other test procedure), suitable special test data registers may be provided on the semi-conductor components tested in each case (e.g. on the above analog and/or digital computing circuits, or on the above semi-conductor memory components (PLAs, PALs, ROMs, RAMs, especially SRAMs and DRAMs, e.g. DDR-DRAMs, etc.).

The test data stored in the respective test data registers may be read from the test data registers by applying a suitable special test data read control signal and a suitable address signal.

The above special test data read control signal has the effect that—in contrast with the use of an ordinary read signal—it is not the memory cells provided in the normal (useful data) memory area of the respective semi-conductor component that are being addressed with the help of the above address signal, but rather corresponding test data registers exactly specified by the relevant address signal.

If for example the above buffered memory modules (“buffered DIMMs”) were to be subjected to an appropriate module test, the problem could occur that the above test data read control signal would not be supported by the protocol of the data buffer components used in each case.

This has the effect that test (result) data stored on the test data registers of each semi-conductor memory component may not be able to be read.

### SUMMARY OF THE INVENTION

The invention is aimed at providing a novel semi-conductor component, as well as a novel process for reading test data.

In one embodiment of the invention, there is a process for reading test data is made available, including:
(a) Reading test data generated during a semi-conductor component test procedure from at least one test data register of a semi-conductor component,
(b) Storing the test data in at least one useful data memory cell provided on the semi-conductor component, and
(c) Reading the test data from the at least one useful data memory cell.

In this way it becomes possible for the test data to be read from the semi-conductor component by means of a (standard) read instruction signal (especially by means of a “read” and/or “standard read” signal) (even when a data buffer component (buffer), not supporting proprietary, direct test data read control signals, were to be connected in series before the semi-conductor component).

In another embodiment of the invention, a semi-conductor component is made available with a plurality of memory cells for the storage of useful data, and at least one test data register for the storage of test data generated during the testing of the semi-conductor component, whereby at least one intermediate register is been provided for buffering the test data stored in the test data register before relaying the test data to at least one of the plurality of memory cells.

### BRIEF DESCRIPTION OF THE DRAWINGS

Below, the invention is more closely described by means of an embodiment example and the attached illustration. In the illustration:

FIG. 1 shows a partially buffered memory module, with corresponding memory components and corresponding data buffer components.

FIG. 2 shows a fully buffered memory module, with corresponding memory components, and corresponding data buffer components.

FIG. 3a shows a section of one of the memory components shown in FIGS. 1 and 2 as an example, in order to illustrate a first procedure step performed during a test data read procedure in terms of an embodiment example of the invention.

FIG. 3b shows a section of one of the memory components shown in FIGS. 1 and 2 as an example, in order to illustrate a second procedure step performed during the test data read procedure.

FIG. 3c shows a section of one of the memory components shown in FIGS. 1 and 2 as an example, in order to illustrate a further procedure step performed during the test data read procedure.

### DETAILED DESCRIPTION OF THE INVENTION

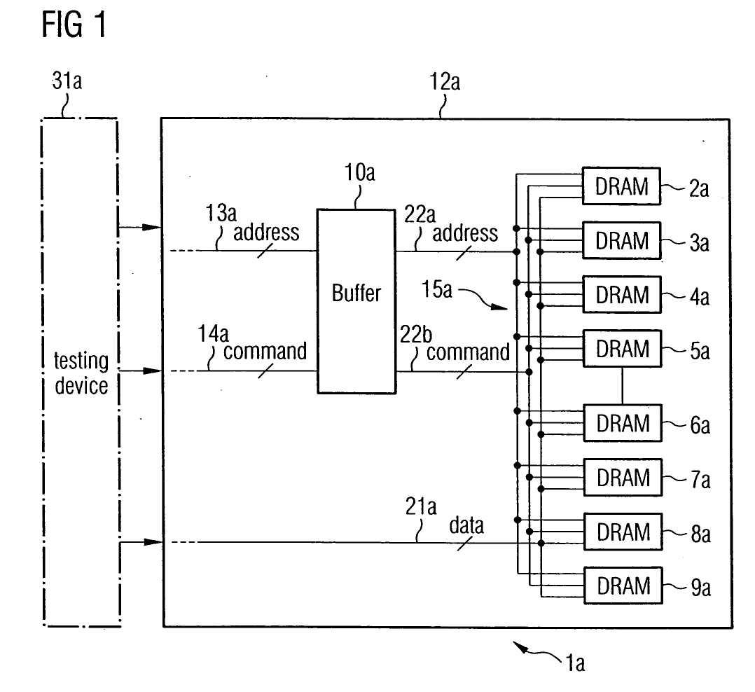

In FIG. 1 a schematic representation of a “partially” buffered memory module 1a is shown (here: a “buffered DIMM” 1a), in which—as an example—a test data read procedure in terms of an embodiment example of the invention can be used.

As is apparent from FIG. 1, the memory module 1a illustrated there comprises numerous memory components 2a, 3a, 4a, 5a, 6a, 7a, 8a, 9a, and—connected in series before the memory components 2a, 3a, 4a, 5a, 6a, 7a, 8a, 9a—one or several data buffer components (“buffers”) 10a.

The memory components 2a, 3a, 4a, 5a, 6a, 7a, 8a, 9a may be function memory or table memory components (e.g. ROMs or RAMs), especially DRAMs, e.g. DDR and/or DDR2-DRAMs, etc.

As is apparent from FIG. 1, the memory components 2a, 3a, 4a, 5a, 6a, 7a, 8a, 9a may be arranged on the same printed circuit board 12a as the buffer 10a.

The buffers 10a may for instance be appropriate Jedec-standardized (“registered DIMM”) DRAM, especially DDR-DRAM and/or DDR2-DRAM data buffer components.

The memory module 1a may be connected with one or more micro-processors—especially by interconnecting a corresponding memory controller (not shown here) (e.g. arranged externally to the memory module 1a, especially arranged externally to the above printed circuit board 12a)—especially with one or more micro-processors of a server or workstation computer (or any other micro-processor, e.g. of a PC, laptop, etc.).

As is apparent from FIG. 1, the address and control signals at the partially buffered memory module 1a shown there—e.g. those emitted by the memory controller, or the respective processor—are not directly relayed to the memory components 2a, 3a, 4a, 5a, 6a, 7a, 8a, 9a.

Instead, the address signals—e.g. via a corresponding address bus 13a (and/or corresponding address lines)—and the control signals—e.g. via a corresponding control bus 14a (and/or corresponding control lines)—are first led to the buffers 10a.

The control signals may be any suitable control signals as used in conventional memory modules, e.g. corresponding read and/or write, and/or chip select (memory component selection) command signals, etc., etc, insofar as they are supported by the protocol of the buffers 10a.

In the buffers 10a the corresponding signals (address signals, control signals) are—briefly—buffered, and relayed—in a chronologically coordinated, and where needed in multiplexed or de-multiplexed fashion—to the memory components 2a, 3a, 4a, 5a, 6a, 7a, 8a, 9a (e.g. via a corresponding—central—memory bus 15a—(with a suitable control and address bus 22a, 22b with corresponding control and address lines)).

With the partially buffered memory module 1a shown in FIG. 1 in contrast, the (useful) data signals—e.g. those emitted by the above memory controller or by the processor in question—can be directly—i.e. without buffering by a corresponding data buffer component (buffer)—relayed to the memory components 2a, 3a, 4a, 5a, 6a, 7a, 8a, 9a (e.g. via a (useful) data bus 21a (and/or corresponding useful data lines) directly connected with the above central memory bus 15a).

Correspondingly inverted, (useful) data signals—emitted by the memory components 2a, 3a, 4a, 5a, 6a, 7a, 8a, 9a—can also be relayed directly—without the inter-connection of a corresponding data buffer component (buffer)—to the memory controller and/or to the respective processor (e.g. again via the above (useful) data bus 21a, which is directly connected with the central memory bus 15a).

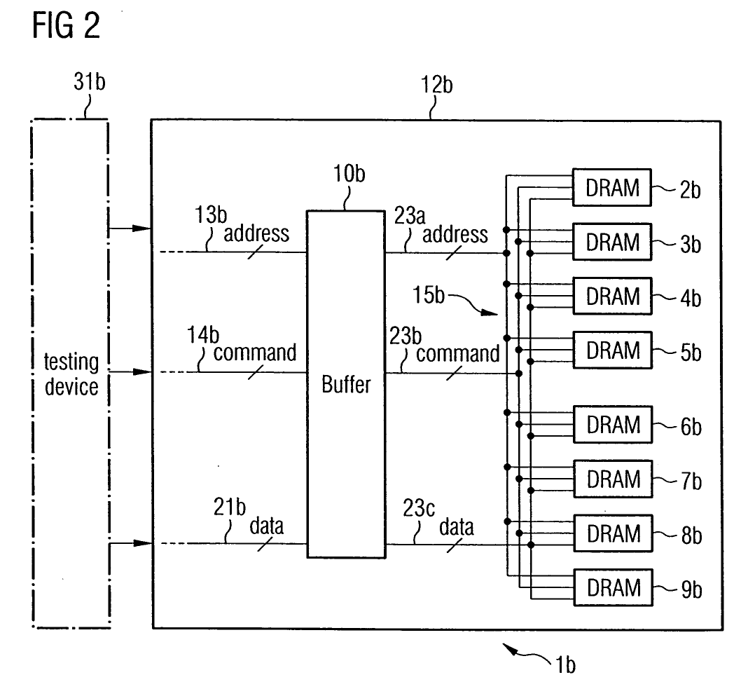

In FIG. 2 a schematic representation of a fully buffered memory module 1b (here: a “buffered DIMM” 1b) is shown, in which the above test data read procedure—more closely described below—can—similarly—be used in terms of an embodiment example of the invention.

As is apparent from FIG. 2, the memory module 1b shown there comprises—corresponding with the partially buffered memory module 1a as in FIG. 1—numerous memory components 2b, 3b, 4b, 5b, 6b, 7b, 8b, 9b and one or more data buffer components (“buffers”) 10b connected in series before the memory components 2b, 3b, 4b, 5b, 6b, 7b, 8b, 9b.

The memory components 2b, 3b, 4b, 5b, 6b, 7b, 8b, 9b may for instance be function memory or table memory components (e.g. ROMs or RAMs), especially DRAMs, e.g. DDR and/or DDR2-DRAMs, etc.

As is apparent from FIG. 2, the memory components 2b, 3b, 4b, 5b, 6b, 7b, 8b, 9b may be arranged on the same printed circuit board 12b as the buffer 10b.

The buffers 10b may be corresponding standardized DRAM, especially DDR-DRAM and/or DDR2-DRAM data buffer components (e.g. “fully buffered” data buffer components standardized by a consortium under leadership of Intel in conjunction with Jedec (e.g. FB-DIMM and/or fully buffered DIMM data buffer components)).

The memory module 1b may be connected (correspondingly similar to the memory module 1a shown in FIG. 1a)—in particular with an inter-connected corresponding memory controller (not shown here and e.g. arranged externally to the memory module 1b, in particular arranged externally to the above printed circuit board 12b)—with one or several micro-processors, particularly with one or several micro-processors of a server or work station computer (or any other suitable micro-processor, e.g. of a PC, laptop, etc.).

As is apparent from FIG. 1 and 2, the memory module 1b shown in FIG. 2 is correspondingly similarly and/or identically constructed as, and operates similarly or identically to, the memory module 1a shown in FIG. 1, except that with the buffer 10b—correspondingly similar to conventional fully buffered memory modules—(in addition to the control—and address—signals buffered correspondingly similar as in the memory module 12a shown in FIG. 1), the (useful) data signals exchanged between the memory controller and/or the respective processor, and the memory components 2b, 3b, 4b, 5b, 6b, 7b, 8b, 9b, are also buffered.

In the buffer 10b the corresponding data signals, e.g. those deriving from the memory controller, and/or the respective processor, e.g. relayed via a data bus 21b, may be—briefly—retained and relayed in a chronologically coordinated, or where appropriate, in a multiplexed or de-multiplexed fashion to the memory components 2b, 3b, 4b, 5b, 6b, 7b, 8b, 9b (e.g. via a—central—memory bus 15b (corresponding with the above central bus 15a described in relation to FIG. 1) (with a corresponding control, address and data bus 23a, 23b, 23c with corresponding control, address and/or data lines)).

In the buffer 10b, correspondingly inverted, the data signals emitted by the memory components 2b, 3b, 4b, 5b, 6b, 7b, 8b, 9b to the above central memory bus 15b, may also be—briefly—buffered and relayed (e.g. via the above data bus 21b)—in a chronologically coordinated, or where appropriate, in a multiplexed or de-multiplexed fashion—to the memory controller and/or the processor in question.

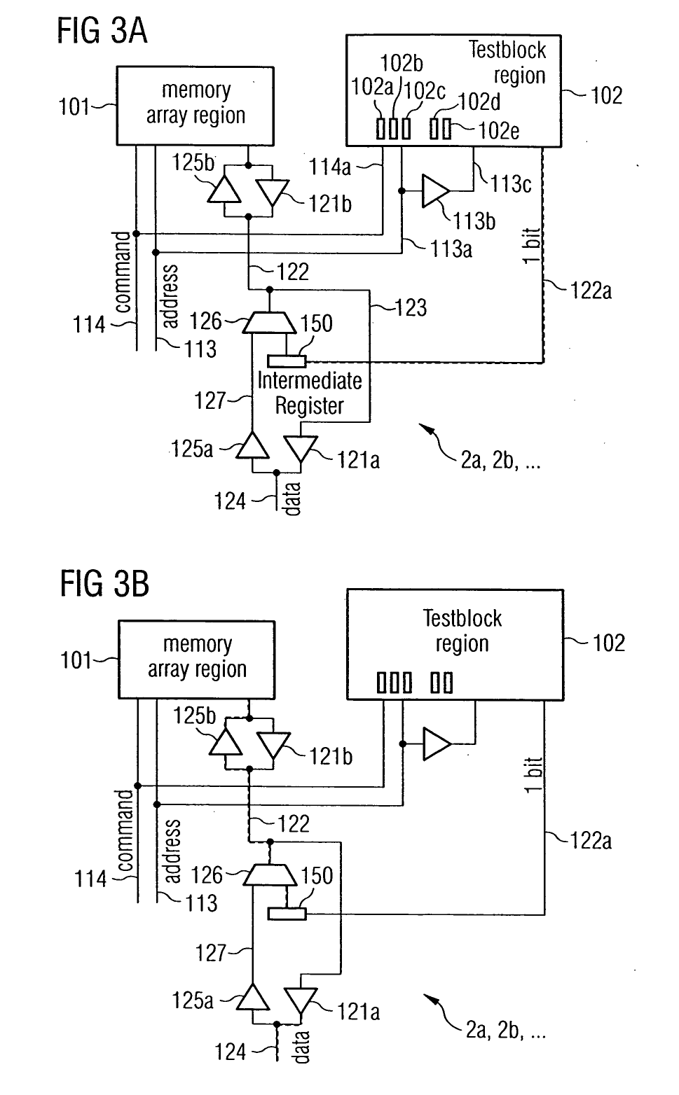

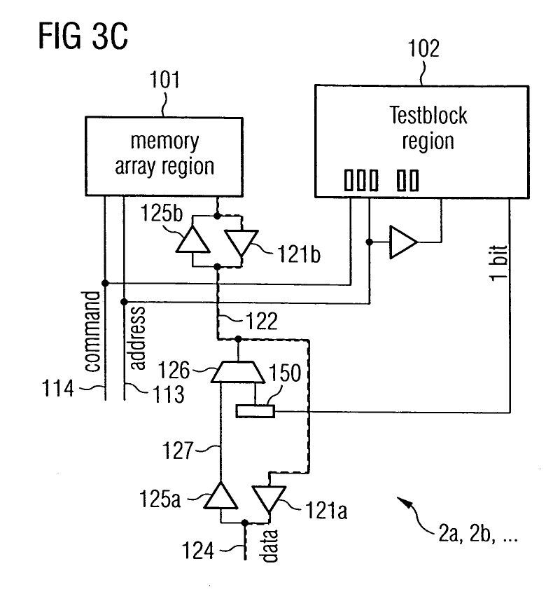

FIG. 3a shows—as an example—a schematic detailed representation of a section of the memory components 2a, 3a, 4a, 5a, 6a, 7a, 8a, 9a, 2b, 3b, 4b, 5b, 6b, 7b, 8b, 9b shown in FIGS. 1 and 2.

The components may—as is apparent from FIG. 3a (and corresponding with conventional memory components, especially DRAMs)—comprise one or more memory array areas and/or memory fields, as well as one or more test block areas 102.

In the memory array area 101 one or several rectangular memory arrays and/or memory matrixes (“memory banks”) can be provided.

Each memory array and/or each memory matrix may in each case comprise numerous memory cells, which may in each case be arranged in numerous rows and columns lying adjacent to each other, so that e.g. more than 16 Mbit, e.g. 32 MBit, 64 MBit, 128 MBit, 256 MBit, etc., or more of data may be stored in each memory array (so that—with for instance four memory arrays—a total memory capacity of e.g. more than 64 Mbit, e.g. 128 MBit, 256 MBit, 512 MBit, 1,024 MBit (and/or 1 GBit) or more is correspondingly created for the memory component).

As is further apparent from FIG. 3a, the memory array area 101 is connected via corresponding lines 114 with the above control bus 22b, 23b (and thereby also with the above control bus 14a, 14b) and via corresponding lines 113 with the above address bus 22a, 23a (and thereby also with the above address bus 13a, 13b).

Furthermore the memory array area 101 is connected with the above data bus 21a, 23c (and thereby also with the above data bus 21b) via corresponding data output driver devices 121a, 121b, and the lines 122, 123, 124 connected with them, so that—by applying an appropriate conventional (DRAM) read instruction signal (“Read” (RD), in particular “Standard Read”, especially a normal “Read” (RD), in particular a “Standard Read” signal as specified by Jedec (and/or Intel/Jedec)) to the above lines 114—the data stored in the memory cells specified by a suitable address signal applied to lines 113, can be read from the respective array in question and emitted to the above lines 124 connected with the above data bus 21a, 23c by means of the data output driver devices 121a, 121b.

As is further apparent from FIG. 3a, the above lines 124—connected with the data-bus 21a, 23c—are also connected with the above memory array area 101 via corresponding data reception devices 125a, 125b, the above lines 122, a multiplexer device 126 and corresponding lines 127 linking the data reception device 125a with the multiplexer device 126.

In this way the effect is achieved that, during the “normal operation” of the memory components 2a, 2b in question, data present on the above lines 124 and relayed by the data reception devices 125a, 125b (and by the multiplexer device 126), may be stored in memory cells—specified by means of an appropriate address signal applied to the lines 113—by applying a corresponding conventional (DRAM) write command signal (“Write” (WT), in particular “Standard Write”, especially a normal “Write” (WT), especially a “Standard Write” signal specified by Jedec (and/or by Intel/Jedec)).

The above write command, read command and address signals etc. may for instance—as already indicated above—be conveyed to the buffers 10a, 10b by the above memory controller and/or by the respective processor in question via the above control and address buses 13a, 13b, 14a, 14b, may be—briefly—buffered, and relayed—in a chronologically co-ordinated fashion—via the above control and address buses 22a, 23a, 22b, 23b to the memory components 2a, 2b, etc.

In order to perform corresponding test procedures, especially corresponding module tests, instead of the above memory controller/processor, appropriate test apparatuses 31a, 31b may—as indicated in FIG. 1 and FIG. 2—be connected to the above memory modules/printed circuit boards 1a, 1b/12a, 12b.

For performing tests, these apparatuses may—correspondingly similar to the above memory controller/processor—convey corresponding (test) control, (test) address and useful (test) data signals via the above control, address and the (useful) data buses 13a, 13b, 14a, 14b, 21a, 21b, to the above buffers 10a, 10b (and thereby to the above memory components 2a, 3a, 4a, 5a, 6a, 7a, 8a, 9a, 2b, 3b, 4b, 5b, 6b, 7b, 8b, 9b) (and may receive corresponding useful (test) data signals from the buffers 10a, 10b (and thereby from the memory components 2a, 3a, 4a, 5a, 6a, 7a, 8a, 9a, 2b, 3b, 4b, 5b, 6b, 7b, 8b, 9b)).

In order to store the data, especially corresponding test result data, generated by the test procedures executed by the test apparatuses 31a, 31b (e.g. corresponding AC or DC tests, or any other test procedure), special test data registers 102a, 102b, 102c, 102d, 102e—as e.g. is shown in FIG. 3a—may be provided in the test block areas 102 of the memory components 2a, 3a, 4a, 5a, 6a, 7a, 8a, 9a, 2b, 3b, 4b, 5b, 6b, 7b, 8b, 9b tested in each case (e.g. between 1 and 100, especially e.g. between 2 and 25 test data registers with a storage capacity of for instance between 1 Bit and 32 Bit each, especially between 1 Bit and 8 Bit, etc.).

As is apparent from FIG. 3a, the test block area 102 is connected with the control bus 22b, 23b (and thereby also with the control bus 14a, 14b) via corresponding lines 114a and the above lines 114.

The test block area 102 is furthermore connected—as is also shown in FIG. 3a—via the above lines 113, corresponding lines 113a, corresponding data reception devices 113b, and corresponding lines 113c to the address bus 22a, 23a (and thereby also to the address bus 13a, 13b), and—via a test data read line 122a (here: a 1 Bit test data read line 122a, (alternatively for instance a 2, 4 or 8 Bit test data read line, etc.))—with an intermediate register 150.

The intermediate register 150 may have a smaller storage capacity than the above test data registers 102a, 102b, 102c, 102d, 102e, e.g.—corresponding with the data width of the above test data read line 122a—e.g. between 1 Bit and 8 Bit, especially between 1 Bit and 4 and/or 2 Bit, for example 1 Bit.

In order to read the test data stored in the relevant test data registers 102a, 102b, 102c, 102d, 102e, a correspondingly suitable special (Jedec (and/or Intel/Jedec)) command signal or command (e.g. a corresponding “TMRS” signal and/or command, and/or register boot signal and/or command), for instance one specified by Jedec (or by the above Intel consortium in conjunction with Jedec), can be applied to the above lines 114 (and if needed, additionally to the lines 113, and/or part of the lines 113) (whereby the TMRS command for instance consists of a special Bit combination applied to the lines 114, and a special Bit combination applied to the lines 113 and/or part of the lines 113 (i.e. a special reserved (partial) address)).

In this way, the effect can be achieved that data stored in that (or in those) relevant test data register(s) 102a, 102b, 102c, 102d, specified by a corresponding address signal applied to the lines 113 (and/or to a further part of the lines 113, which is present in addition to the above part of the lines 113), and for instance relayed simultaneously with the TMRS command, is read from that (or those) relevant test data register(s) 102a, 102b, 102c, 102d, 102e, relayed in serial (or alternatively in parallel) fashion via the test data read line 122a (indicated in FIG. 3a by a hatched line) to the intermediate register 150, and stored there.

The above “TMRS” signal and/or command, and/or register boot signal and/or command, and the address signal required in each case, may be applied by the relevant test apparatus 31a, 31b to the above control bus 14a, 14b and/or address bus 13a, 13b and relayed to the buffers 10a, 10b, and can from there be relayed via the above control bus 22b, 23b/the above lines 114, and/or the above address bus 22a, 23a/the above lines 113 to the relevant memory component 2a, 2b.

As is for instance shown in FIG. 3b, the effect can be achieved—e.g. in response to the above special Jedec (and/or Intel/Jedec) command signal and/or command, especially the above “TMRS” signal and/or command—that not the above lines 127, and/or the data reception device 125a are connected via the multiplexer device 126 with the lines 122, and with the data reception device 125b (which would otherwise be the case during the “normal operation” of the memory components 2a, 2b), but rather—by means of an appropriate switching over of the multiplexer device 126—that the intermediate register 150 is connected with the lines 122, and with the data reception device 125b (“test operation”).

By means of applying an ordinary (DRAM) write command signal (“write” (WT), especially “standard write” signal, in particular a normal “write”, especially a “standard write” signal specified by Jedec (and/or Intel/Jedec)) to the above lines 114, the effect can be achieved that the test data stored in the intermediate register 150 is read from the intermediate register 150, relayed via the multiplexer device 126 and the lines 122 to the data reception device 125b and then stored in one or several memory cells (chosen at will) of the memory array area 101 specified by means of an appropriate address signal applied to the lines 113 (in fact in serial (or alternatively in parallel) fashion, as is indicated in FIG. 3b by means of the hatched line).

The above “write”, and/or “standard write” signal, and the address signal required in each case, can by applied by the relevant test apparatus 31a, 31b to the above control bus 14a, 14b and/or address bus 13a, 13b, relayed to the buffers 10a, 10b and relayed from there via the above control bus 22b, 23b/the above lines 114, and/or the above address bus 22a, 23a/the above lines 113, to the memory component 2a, 2b in question.

Next, by applying a common (DRAM) read instruction signal (“Read” (RD), especially “Standard Read” signal, in particular a normal “Read” (RD) signal, especially a “Standard Read” signal specified by Jedec (and/or Intel/Jedec) to the above lines 114, the effect can be achieved that the test data stored in that (or those) memory cell(s) of the memory array area 101—specified by means of an address signal applied to lines 113—is read from that and/or those memory cells of the memory array areas 101 and relayed via the data output driver device 121b, the lines 122, 123, and the data output driver device 121a, to the lines 124, and thereby to the data bus 21a, 23c, and thereby—where needed with the buffer 10b, and the data bus 21b interconnected—to the relevant test apparatus 31a, 31b (as is indicated in FIG. 3c by means of a hatched line).

The above “Read” and/or “Standard Read” signal, and the corresponding address signal can be applied by the relevant test apparatus 31a, 31b to the above control bus 14a, 14b and/or address bus 13a, 13b, relayed to the buffers 10a, 10b, and relayed from there via the above control bus 22b, 23b/the above lines 114, and/or the above address bus 22a, 23a/the above lines 113, to the relevant memory component 2a, 2b.

The received test data can then be evaluated in the test apparatus 31a, 31b in question in a conventional fashion.

If the storage capacity of the intermediate register 150 (and/or the data width of the test data read line 122a) is smaller than the data quantity of the test data to be read from the test data register(s) 102a, 102b, 102c, 102d, 102e in each case, the test data to be read can be partitioned and read step by step in succession (by means of serially emitted sequences of corresponding register boot (TMRS) and write commands and/or signals) from the test data registers 102a, 102b, 102c, 102d, 102e, buffered in the intermediate register 150 and written into corresponding memory cells of the memory array area 101, and then read by means of one or several corresponding read signals from these memory cells and relayed to the relevant test apparatus 31a, 31b (in fact for instance in parallel fashion (e.g. even when the data has in each case been relayed to the intermediate register 105 in serial fashion)).

By means of the operational method described above, the following result can be achieved, namely that the test data stored in the test data registers 102a, 102b, 102c, 102d, 102e can be read from them and relayed to the relevant test apparatus 31a, 31b, even when the above buffers 10a, 10b do not support corresponding direct proprietary test data read control signals.

What is claimed is:

1. A process for reading test data, comprising:
reading test data generated during a semi-conductor component test procedure from at least one test data register of a semi-conductor component;
storing the test data in at least one useful data memory cell provided on the semi-conductor component; and
reading the test data from the at least one useful data memory cell.

2. The process according to claim 1, wherein the semi-conductor component comprises a plurality of useful data memory cells arranged in a memory array area.

3. The process according to claim 1, wherein the semi-conductor component comprises a plurality of test data registers arranged in a test block area.

4. The process according to claim 1, wherein the test data read from the at least one test data register is buffered in at least one intermediate register.

5. The process according to claim 4, wherein the test data buffered in the at least one intermediate register is read from the at least one intermediate register and stored in the at least one useful data memory cell.

6. The process according to claim 1, wherein the semi-conductor component is a memory component.

7. The process according to claim 6, wherein the memory component is a RAM.

8. A semi-conductor component, comprising:
a plurality of memory cells for storage of useful data;
at least one test data register for the storage of test data generated during the testing of the semi-conductor component; and
at least one intermediate register provided for buffering the test data stored in the test data register before relaying the test data to at least one of the plurality of memory cells.
